(19) United States
(12) Patent Application Publication
(10) Pub. No.: US 2024/0356545 A1
(43) Pub. Date: Oct. 24, 2024

(54) SWITCHING CIRCUIT FOR POWER MANAGEMENT CIRCUITS AND FRONT-END MODULES (FEMS)

(71) Applicant: Qorvo US, Inc., Greensboro, NC (US)

(72) Inventors: Baker Scott, San Jose, CA (US); Douglas R. Farrenkopf, Carlsbad, CA (US); Nadim Khlat, Cugnaux (FR); George Maxim, Saratoga, CA (US); Christopher T. Brown, Sunnyvale, CA (US); Michael R. Kay, Summerfield, NC (US)

(21) Appl. No.: 18/627,676

(22) Filed: Apr. 5, 2024

Related U.S. Application Data
(60) Provisional application No. 63/460,410, filed on Apr. 19, 2023.

(51) Int. Cl. H03K 17/687; H02M 3/07; H02M 3/158; H03K 17/06

(52) U.S. Cl. CPC H03K 17/6872; H02M 3/07; H02M 3/1582; H03K 17/063

(57) ABSTRACT

A switching circuit for power management circuits and front-end modules (FEMs) is disclosed. In one aspect, a switching circuit is made from N-type field effect transistors (NFETs) that couple directly to charge pumps associated with converters in the power management circuits. The charge pumps provide a desired gate bias for the NFETs to allow for low loss across the source drain of the NFET. By providing such an NFET-based switching circuit, different FEMs may be coupled to different converters across a wide voltage range. NFETs are smaller than comparable P-type FETs (PFETs) and require less control circuitry. Accordingly, space and cost may be reduced while still providing desired performance across a desired voltage range.

### PRIORITY APPLICATION

This application claims the benefit of U.S. Provisional Patent Application Ser. No. 63/460,410, filed on Apr. 19, 2023, entitled “SWITCHING CIRCUIT FOR POWER MANAGEMENT CIRCUITS AND FRONT-END MODULES (FEMS),” the disclosure of which is hereby incorporated herein by reference in its entirety.

### BACKGROUND

### I. Field of the Disclosure

The technology of the disclosure relates generally to a switching circuit configured to couple a power management circuit, including a converter (e.g., a direct current-to-direct current (DC-DC) converter) to a front-end module.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to reduce power consumption. Power consumption has been reduced through a proliferation of power management circuits in transceiver architectures. These power management circuits may provide tailored supply voltages to front-end modules (FEMs) and make the FEMs more efficient for the desired power savings. However, where multiple power management circuits or different converters are in use, there may be a switching circuit that couples elements of the FEM to the different converters. Optimizing such switching circuitry offers opportunities for innovation.

### SUMMARY

Aspects disclosed in the detailed description include a switching circuit for power management circuits and front-end modules (FEMs). In particular, exemplary aspects contemplate a switching circuit made from N-type field effect transistors (NFETs) that couples directly to charge pumps associated with converters in the power management circuits. The charge pumps provide a desired gate bias for the NFETs to allow for low loss across the source drain of the NFET. By providing such an NFET-based switching circuit, different FEMs may be coupled to different converters across a wide voltage range. NFETs are smaller than comparable P-type FETs (PFETs) and require less control circuitry. Accordingly, space and cost may be reduced while still providing desired performance across a desired voltage range. Further aspects disclose a specific current mirror feedback loop circuit that may be used as part of a control circuit for the switches of the present disclosure.

In this regard, in one aspect, a power management system is disclosed. The power management system includes a charge pump and a direct current-to-direct current (DC-DC) converter coupled to the charge pump. The power management system also includes a switching network coupled to the DC-DC converter and a control circuit coupled to the charge pump and the switching network; the control circuit is configured to route power from the charge pump to a switch within the switching network.

In another aspect, a mobile terminal comprising a power management system is disclosed. The power management system includes a power management chip comprising a first charge pump and a first direct current-to-direct current (DC-DC) converter coupled to the first charge pump. The power management system further includes a switching network coupled to the first DC-DC converter and a control circuit coupled to the first charge pump and the switching network, the control circuit configured to route power from the first charge pump to a switch within the switching network and a first front-end module coupled to the switching network.

In another aspect, a switching network is disclosed. The switching network includes a first NFET configured to be coupled to a direct current-to-direct current (DC-DC) converter. The switching network further includes a control circuit coupled to a gate of the first NFET and configured to be coupled to a charge pump associated with the DC-DC converter and use power from the charge pump to bias the gate of the first NFET.

In another aspect, a method for controlling a switching circuit is disclosed. The method includes, responsive to receiving information from an external source, activating one or more charge pumps and turning on one or more NFET switches to couple at least one of the one or more charge pumps to a front-end module FEM).

### BRIEF DESCRIPTION OF THE DRAWINGS

FIG. 1 is a block diagram of a conventional system having multiple power management circuits, including multiple direct current-to-direct current (DC-DC) converters coupled to multiple front-end modules (FEMs) through switching circuitry to highlight limitations of conventional approaches;

FIG. 2 is a hybrid block and circuit diagram of an exemplary system with a switching circuit on a power management die according to an exemplary aspect of the present disclosure;

FIG. 3 is a block diagram of an exemplary system with an expanded switching circuit of FIG. 2 coupled to a plurality of FEMs according to an exemplary aspect of the present disclosure;

FIG. 4 is a block diagram of the system of FIG. 3 in a particular exemplary use case with the switching circuit configured to activate two FEMs;

FIG. 5 is a block diagram of the system of FIG. 3 in a second exemplary use case with the switching circuit configured to activate three FEMs;

FIG. 6 is a block diagram of the system of FIG. 3 in a third exemplary use case with the switching circuit configured to activate a single FEM;

FIG. 7 is a flowchart illustrating a process of using the system of FIG. 2 or 3;

FIG. 8 is a circuit diagram of a control circuit for use with a switch used in the switching circuit of the system of FIG. 2 or 3;

FIG. 9 is a circuit diagram of an alternate control circuit for use with a switch used in the switching circuit of the system of FIG. 2 or 3; and

FIG. 10 is an expanded circuit diagram of the control circuit of FIG. 8, where cascoded field effect transistors (FETs) may be used for different ones of the FETs illustrated in FIG. 8;

FIG. 11 is a block diagram of an exemplary die layout illustrating the space-saving aspects of the system of FIG. 2 or 3; and

FIG. 12 is a block diagram of a mobile terminal, which may include the system of FIG. 2 or 3 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Aspects disclosed in the detailed description include a switching circuit for power management circuits and front-end modules (FEMs). In particular, exemplary aspects contemplate a switching circuit made from N-type field effect transistors (NFETs) that couples directly to charge pumps associated with converters in the power management circuits. The charge pumps provide a desired gate bias for the NFETs to allow for low loss across the source-drain of the NFET. By providing such an NFET-based switching circuit, different FEMs may be coupled to different converters across a wide voltage range. NFETs are smaller than comparable P-type FETs (PFETs) and require less control circuitry. Accordingly, space and cost may be reduced while still providing desired performance across a desired voltage range. Further aspects disclose a specific current mirror feedback loop circuit that may be used as part of a control circuit for the switches of the present disclosure.

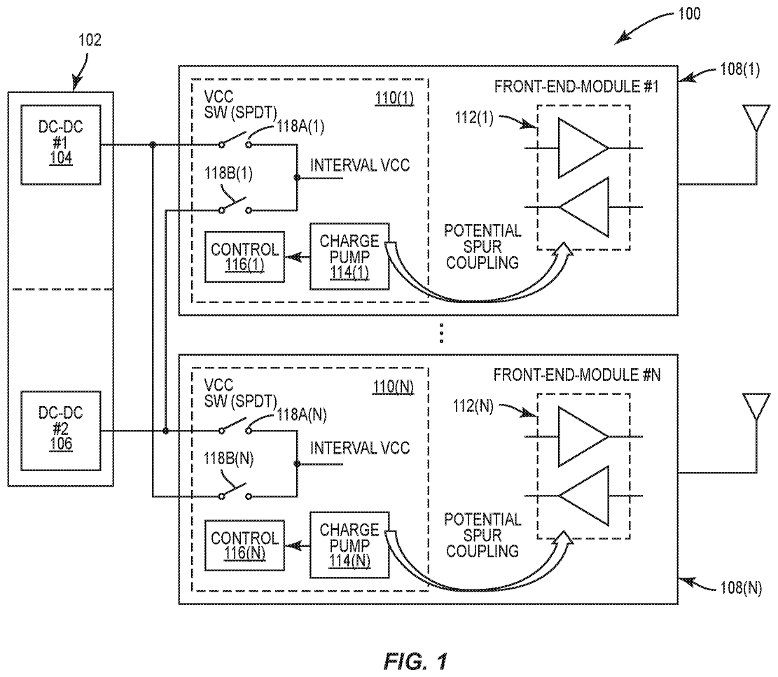

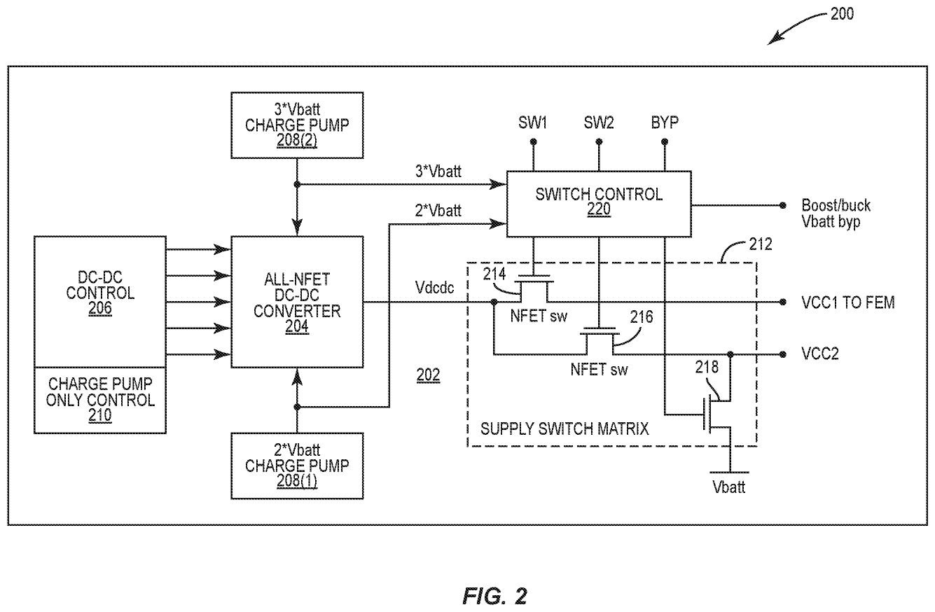

Before addressing particulars of the present disclosure, a brief overview of a system having multiple power management circuits collectively having multiple direct current-to-direct current (DC-DC) converters and multiple FEMs is provided with reference to FIG. 1 to highlight the limitations of existing switching solutions. Discussion of aspects of the present disclosure begins below with reference to FIG. 2.

In this regard, FIG. 1 is a block diagram of a conventional system 100 having a power management circuit 102, which may include DC-DC converters 104 and 106. Note that these DC-DC converters 104 and 106 may be co-located on a single die or may be on different dies. Likewise, while drawn as a single-element power management circuit 102, it should be appreciated that multiple power management chips are sometimes used.

With continued reference to FIG. 1, the power management circuit 102 may be coupled to a plurality of FEMs 108(1)-108(N). Historically, each FEM 108(1)-108(N) may include a respective switching circuit 110(1)-110(N) that provides a supply voltage signal to respective power amplifier elements 112(1)-112(N) in the FEMs 108(1)-108(N). Further, each switching circuit 110(1)-110(N) may include a respective charge pump 114(1)-114(N), a respective control circuit 116(1)-116(N) and switches 118A(1)-118A(N), 118B(1)-118B(N). If more than two DC-DC converters are present, there may be additional switches in parallel with switches 118A, 118B, as can be readily extrapolated.

It should be appreciated that the charge pumps 114(1)-114(N) may take up space in the respective FEM 108(1)-108(N). By having the charge pump 114(1)-114(N) in the FEMs 108(1)-108(N), there is a risk that spurs from the charge pumps 114(1)-114(N) may couple, crosstalk, or otherwise cause interference for the power amplifier elements 112(1)-112(N). In addition to the size and crosstalk issues, the switches 118A(1)-118A(N), 118B(1)-118B(N) may be PFETs or NFET/PFET hybrids to allow for a full range of desired voltages to pass through the switches 118(1)-118A(N), 118B(1)-118B(N). That is, PFETs are usually used in conventional systems, but PFETs do not have the same voltage pass range as NFETs and thus must be made bigger. Where the PFET cannot accommodate the full range of the desired voltages, a hybrid PFET/NFET switch circuit may be used. The addition of the NFET adds even more area to the switching circuit.

In short, existing solutions have some challenges. Exemplary aspects of the present disclosure contemplate moving the switching circuit to the power management die so that charge pumps associated with the DC-DC converters may also be used by the switching circuit, thereby avoiding duplication of charge pump circuitry. Even if the charge pumps are not reused, removing the switching circuit charge pumps from the FEMs reduces the chance of spur coupling crosstalk. Further, aspects of the present disclosure rely on NFET switches. While normally an NFET would be limited by the requirement for high voltage levels to create a needed gate bias, the proximity to the charge pumps of the DC-DC converters provides a ready solution for these elevated voltage levels, as explained in greater detail below.

FIG. 2 provides a simplified hybrid block and circuit diagram of an exemplary aspect of the present disclosure. Specifically, a system 200 may have a power management chip or die 202 with a DC-DC converter 204 that may be made from NFETs. The DC-DC converter 204 may be controlled by a control circuit 206. The control circuit 206 may also control charge pumps 208(1), 208(2) (and optionally more if needed or desired), which can provide voltage levels above a standard battery voltage rail level (i.e., Vbatt) (e.g., 2*Vbatt or 3*Vbatt as illustrated). Alternatively, the charge pumps 208(1), 208(2) may be controlled by a charge pump control circuit 210. Such independent control circuit 210 may be appropriate when the DC-DC converter 204 is turned off, but a desired bypass voltage is desired.

The power management chip or die 202 also includes a switch matrix 212 with multiple NFET switches 214, 216, 218 therein. The switches 214, 216, 218 are controlled by a switch control circuit 220. The switch control circuit 220 receives signals indicating which switches 214, 216, and 218 are open or closed and, thus, what signals pass to an associated FEM (not shown in FIG. 2). The switch control circuit 220 also receives voltage signals from the charge pumps 208(1), 208(2) to provide appropriate gate bias to the switches 214, 216, 218. Note that switch 218 may be a bypass switch that merely provides a normal battery voltage rail voltage (i.e., Vbatt) at the output.

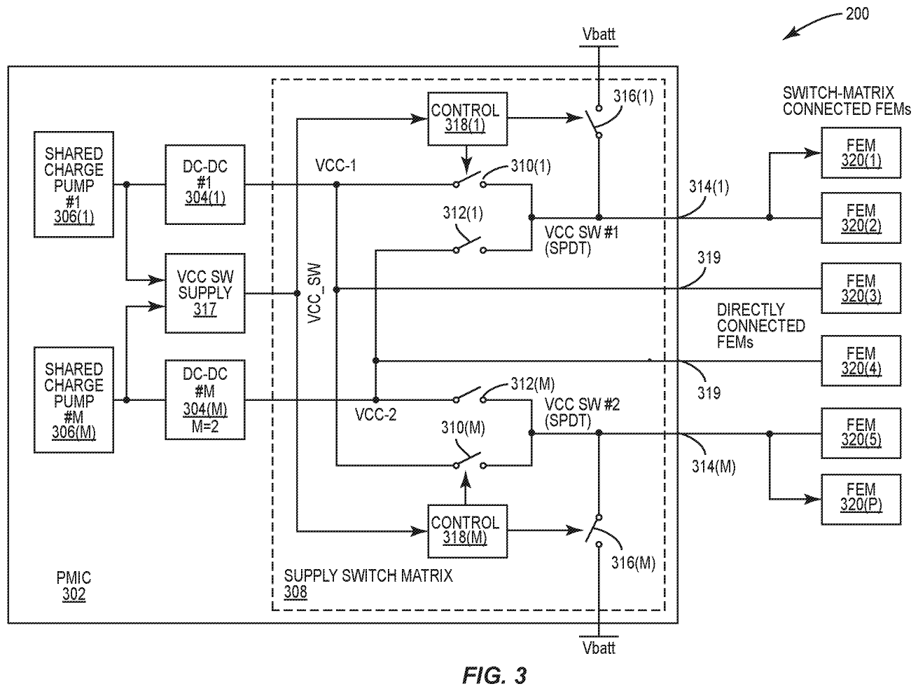

FIG. 3 provides a block diagram of the system 200 having an expanded power management die 302 with a plurality of DC-DC converters 304(1)-304(M) (where, as shown, M=2, although more can be present), each with a respective charge pump 306(1)-306(M) and a switching circuit 308 (also sometimes referred to as a switching matrix). The switching circuit 308 includes a first plurality of NFET-based switches 310(1)-310(M) that couple to the DC-DC converter 304(1) and a second plurality of NFET-based switches 312(1)-312(M) that couple to the DC-DC converter 304(M). If more DC-DC converters are present, additional pluralities of switches would be present in parallel, as can be readily extrapolated. The switches 310(1) and 312(1) couple to a first output 314(1) while the switches 310(M) and 312(M) couple to an Mth output 314(M). Respective bypass switches 316(1)-316(M) also couple to the outputs 314(1)-314(M). Control circuits 318(1)-318(M) are used to control the switches for respective outputs 314(1)-314(M). Additional outputs 319 may also be present if desired. Note that the charge pumps 306(1)-306(M) are also coupled to the control circuits 318(1)-318(M) through a switch supply circuit 317. The control circuits 318(1)-318(M) may use this power from the charge pumps 306(1)-306(M) to bias a gate of the NFET switches, as better explained below.

FEMs 320(1)-320(P) may be coupled to the outputs 314(1)-314(M) and 319. This arrangement provides great flexibility in how active FEMs 320(1)-320(P) are provided supply voltages. That is, FEMs 320(1), 320(2) may be supplied power from the first DC-DC converter 304(1), the second DC-DC converter 304(2), or from the battery through the bypass switch 316(1). FEM 320(3) may receive power directly from the first DC-DC converter 304(1). FEM 320(4) may receive power directly from the second DC-DC converter 304(2). FEMS 320(5) and 320(6) may receive power from the first DC-DC converter 304(1), the second DC-DC converter 304(2), or from the battery through the bypass switch 316(2). It should be appreciated that other variations are possible.

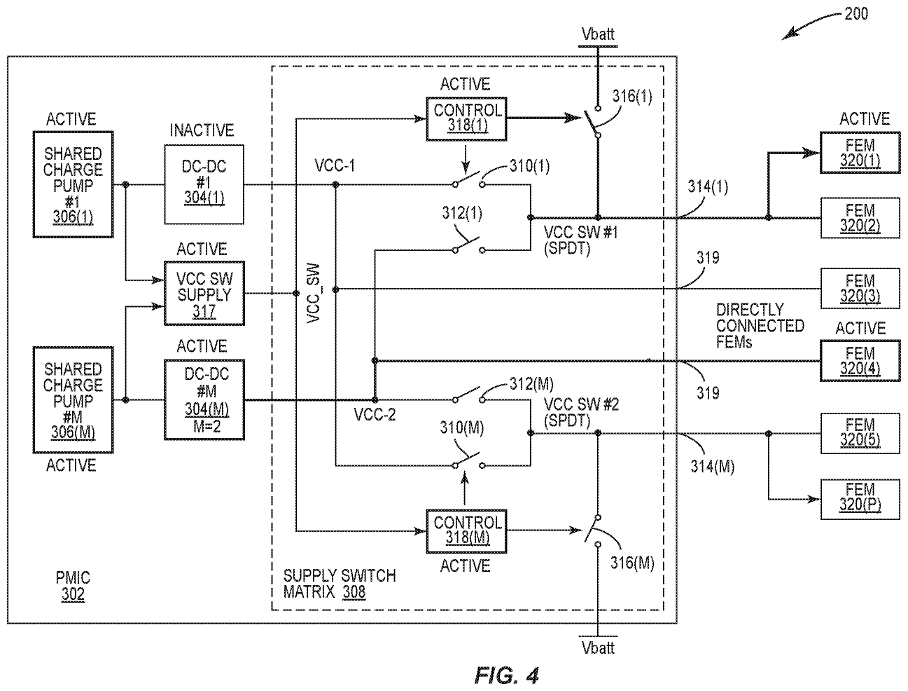

FIGS. 4-6 illustrate possible use cases of the system 200. In FIG. 4, the FEMs 320(1) and 320(4) are active by virtue of the switch 316(1) being turned on and other switches being turned off. This means that the FEM 320(1) is receiving the bypass battery voltage signal, and the FEM 320(4) is receiving the signal from the second DC-DC converter 304(2). Note that in this case, the first DC-DC converter 304(1) may be put into a low-power or inactive state to prevent the FEM 320(3) from being activated.

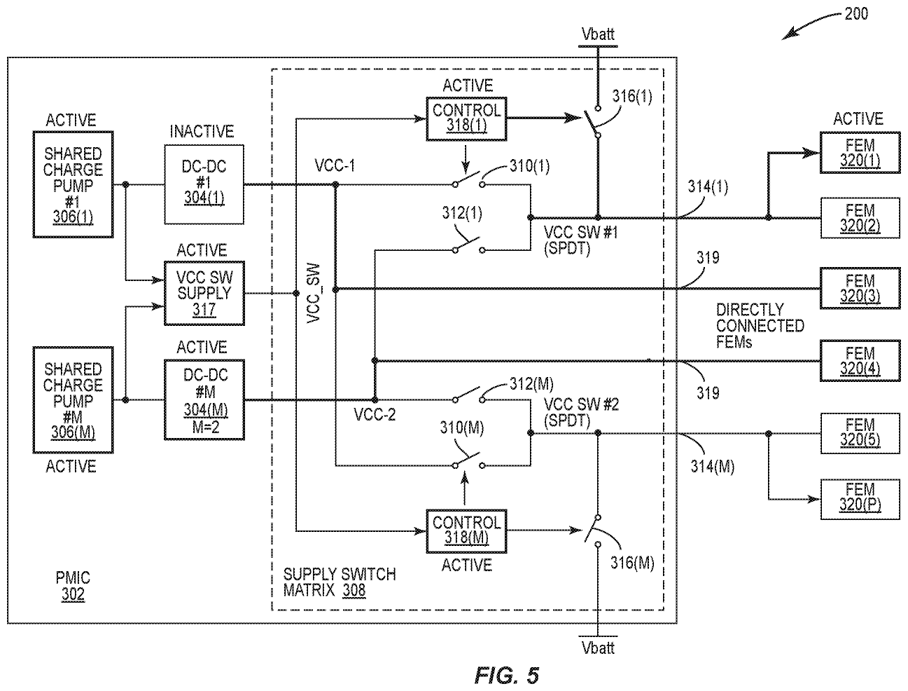

In FIG. 5, the FEMS 320(1), 320(3), and 320(4) are active by virtue of the switch 316(1) being turned on and other switches being turned off. As with FIG. 4, the FEM 320(1) receives the bypass battery voltage signal, and the FEM 320(4) receives the signal from the second DC-DC converter 304(2). Additionally, the first DC-DC converter 304(1) provides a signal to the FEM 320(3). Here, both DC-DC converters 304(1), 304(2) are active as are both charge pumps 306(1), 306(2).

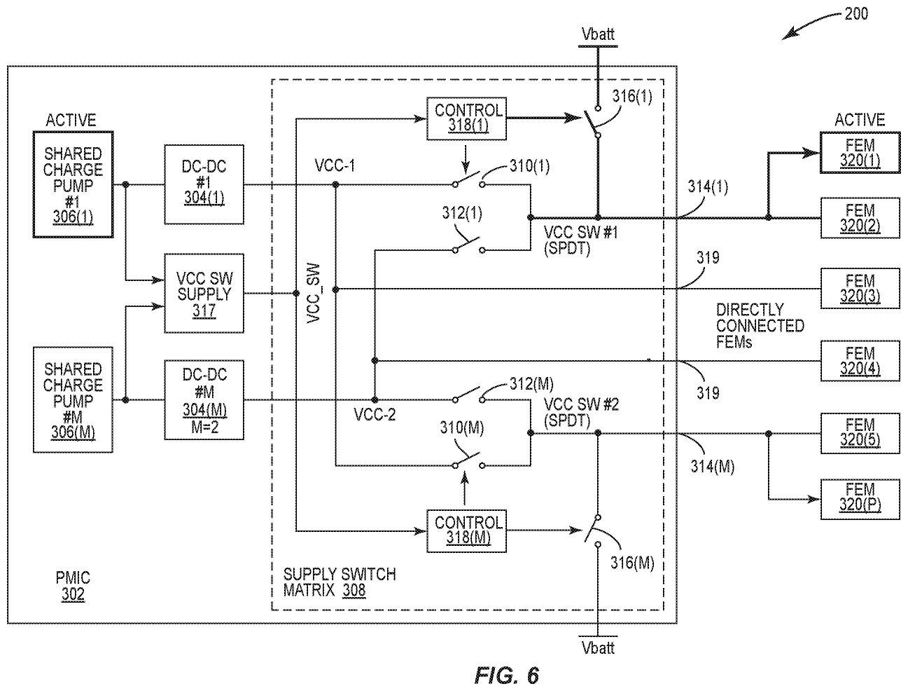

In FIG. 6, only FEM 320(1) is active, and FEM 320(1) is biased directly from Vbatt through the bypass switch 316(1). Both DC-DC converters 304(1), 304(2) may be inactive. Similarly, the second charge pump 306(2) may be inactive. The charge pump 306(1) provides power to the control circuit 318(1) to activate the switch 316(1).

While three use cases are shown, and in each case, a FEM is in bypass mode, the present disclosure is not so limited, and other combinations of active modes may be present (e.g., two FEMs active, one using the first DC-DC converter 304(1) and the other using the second DC-DC converter 304(2); one FEM active using only one of the DC-DC converters, etc.). Note that this variety of configurations may require a specialized state machine that allows the different DC-DC converters to move from buck to boost modes and between different boost modes (e.g., 2*Vbatt or 3*Vbatt) and/or activation of charge pumps without activating the DC-DC converter.

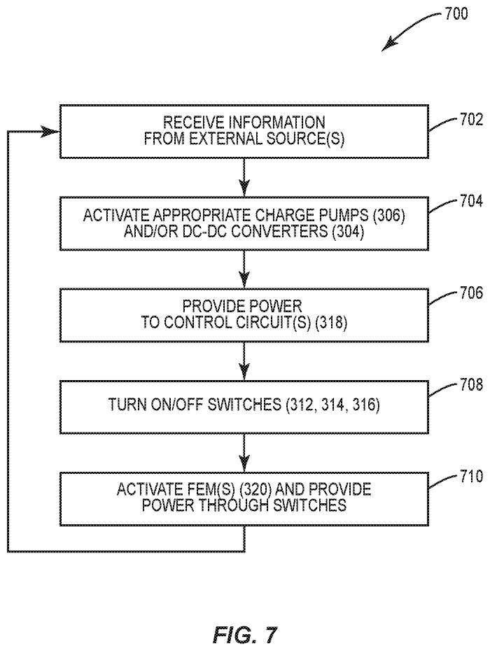

FIG. 7 provides a flowchart of a process 700 for using the system 200. The process 700 begins when the system 200 receives information from one or more external source(s) (block 702), such as a baseband processor, an application processor, or the like. This information may include a desired signal to be transmitted, a power level at which the signal is to be transmitted, channel conditions, a modulation scheme, or the like. However, from this information, the control circuit 206 and/or the control circuit 210 may activate appropriate charge pumps 306 and/or DC-DC converters 304 (block 704). The activated elements may provide power to the control circuits 318 (block 706). Note that not all control circuits 318(1)-318(M) may be activated. The control circuits 318 may then turn on and off the appropriate switches 310, 312, 316 (block 708). Where a switch is turned on, the control circuit 318 may use power provided by the charge pumps 306 to bias the gate of the NFETs used in the switches. The process 700 continues by activating FEMs 320 and providing power thereto through the switches (block 710). Note that in some use cases, power may be provided without having to go through a switch (e.g., FEMs 320(3), 320(4)). The process 700 may end once transmission is concluded, or the process 700 may iterate through another loop if more information is received from the external sources (block 702).

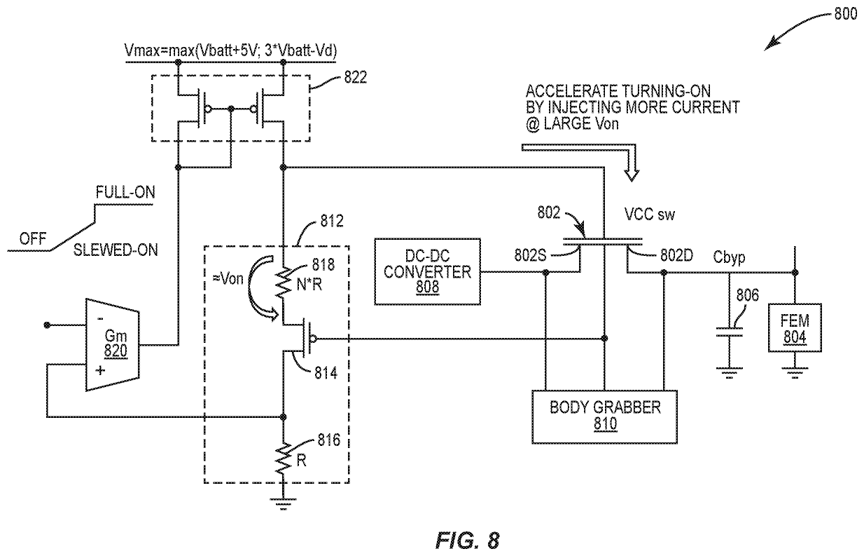

While the above discussion focuses on the system 200, it should be appreciated that the present disclosure also provides details about the actual switching circuitry with reference to FIGS. 8-10. While specific details are presented, it should be appreciated that there may be other structures that work with the system 200.

In this regard, FIG. 8 provides a circuit diagram of a switch circuit 800 that may be used for switches 214, 216, 218, 310, 312, or 316. The switch circuit 800 may include an NFET 802 that is configured to be coupled from a drain 802D to a FEM 804. There may be a bypass capacitor 806 present to assist in transitions between power levels. A source 802S of the NFET 802 is coupled to a DC-DC converter 808, which may be the DC-DC converter 204 or 304.

A body grabber circuit 810 connects the body of the NFET 802 to the side of the NFET 802 that has a lower voltage, preventing a diode forward bias condition.

A Von detector circuit 812 senses the body voltage as well with a source follower 814 that subtracts a nominal threshold voltage formed by a resistor 816. A resistor 818 in the Von detector circuit 812 is coupled to the gate of the NFET 802 and the source follower 814. A voltage drop approximately equal to Von will appear across the resistor 818. The Von voltage is processed by the source follower 814 and applied to a non-inverting input of a transconductance stage 820 to close a negative feedback loop. The transconductance stage 820 generates a current that goes through a mirror 822, which is then injected into the gate of the NFET 802. Thus, when a larger Von is sensed, a larger current is injected at the gate of the NFET 802 to accelerate the turn-on of the NFET 802.

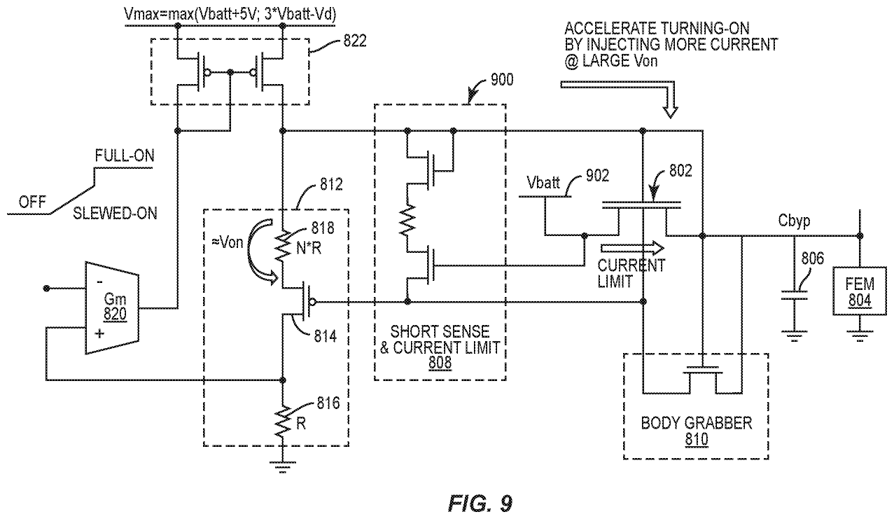

Providing a current sense and limiting circuit at various places in the present disclosure may be beneficial. For example, such a limiting circuit could be present at the bypass switches and/or other switches. Such a limiting circuit 900 is illustrated in FIG. 9, where the NFET 802 is coupled to Vbatt source 902 instead of a DC-DC converter. The limiting circuit 900 measures a voltage across the drain to the source of the NFET 802 and compares this value with a reference voltage.

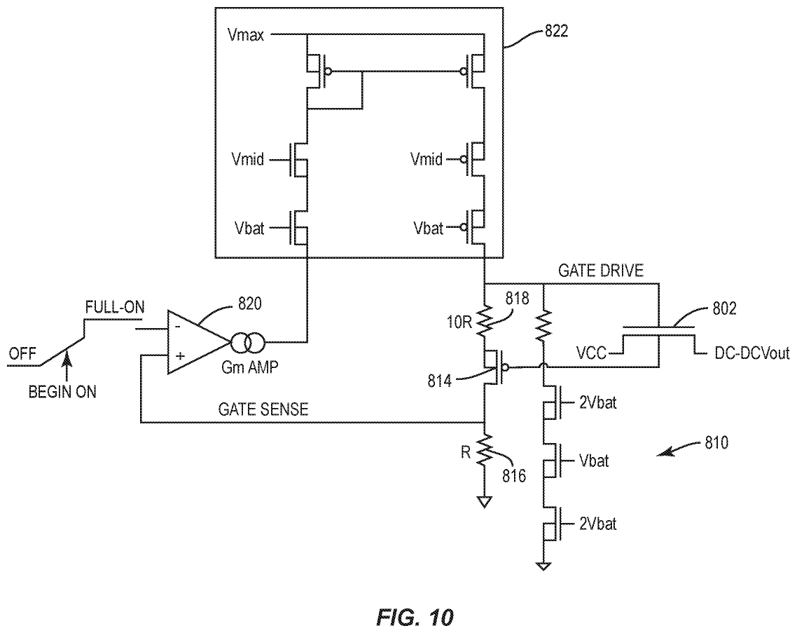

It should be appreciated that the NFET 802 and other FETs described herein may, in fact, be cascoded FETs, as better illustrated in FIG. 10, where the mirror 822 and the body grabber circuit 810 both have multiple cascoded FETs.

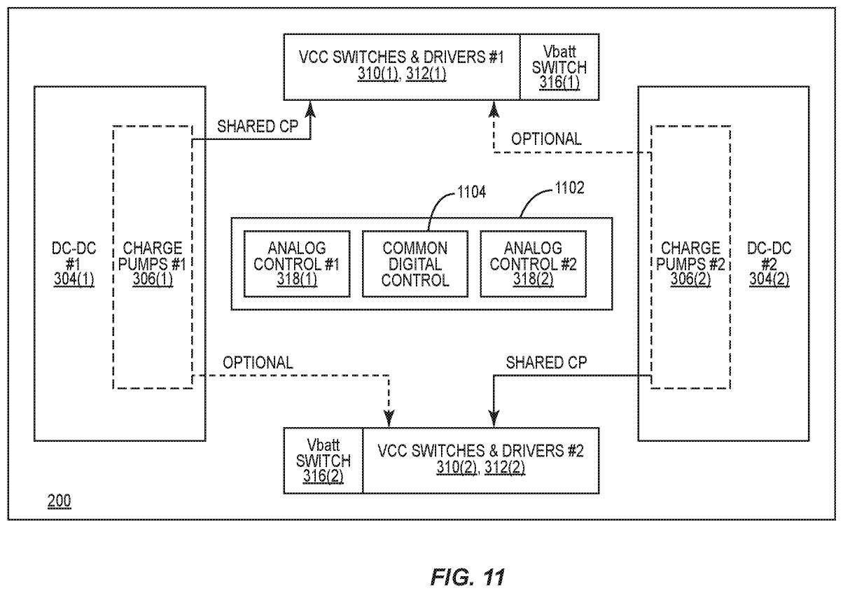

The net result of the circuits proposed herein is a space-saving device that reduces the chance of unwanted crosstalk. An exemplary layout for the system 200 is provided in FIG. 11, where a control circuit 1102 may include a digital control circuit 1104 as well as the control circuits 318(1), 318(2).

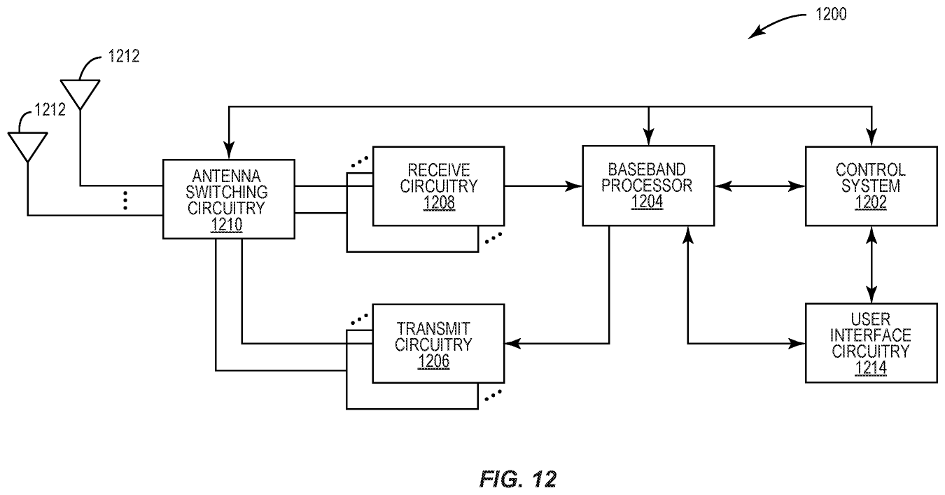

With reference to FIG. 12, the concepts described above may be implemented in various types of user elements 1200, such as mobile terminals, smart watches, tablets, computers, navigation devices, access points, and like wireless communication devices that support wireless communications, such as cellular, wireless local area network (WLAN), Bluetooth, and near field communications. The user elements 1200 will generally include a control system 1202, a baseband processor 1204, transmit circuitry 1206, receive circuitry 1208, antenna switching circuitry 1210, multiple antennas 1212, and user interface circuitry 1214. In a non-limiting example, the control system 1202 can be a field-programmable gate array (FPGA) or an application-specific integrated circuit (ASIC), as an example. In this regard, the control system 1202 can include at least a microprocessor(s), an embedded memory circuit(s), and a communication bus interface(s). The receive circuitry 1208 receives radio frequency signals via the antennas 1212 and through the antenna switching circuitry 1210 from one or more base stations. A low noise amplifier and a filter of the receive circuitry 1208 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1204 processes the digitized received signal to extract the information or data bits conveyed in the received signal. This processing typically comprises demodulation, decoding, and error correction operations. The baseband processor 1204 is generally implemented in one or more digital signal processors (DSPs) and ASICs.

For transmission, the baseband processor 1204 receives digitized data, which may represent voice, data, or control information, from the control system 1202, which it encodes for transmission. The encoded data is output to the transmit circuitry 1206, where a digital-to-analog converter(s) (DAC) converts the digitally encoded data into an analog signal, and a modulator modulates the analog signal onto a carrier signal that is at a desired transmit frequency or frequencies. A power amplifier controlled by the power management circuits of the present disclosure will amplify the modulated carrier signal to a level appropriate for transmission and deliver the modulated carrier signal to the antennas 1212 through the antenna switching circuitry 1210 to the antennas 1212. The multiple antennas 1212 and the replicated transmit and receive circuitries 1206, 1208 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A power management system comprising:
a charge pump;
a direct current-to-direct current (DC-DC) converter coupled to the charge pump;
a switching network coupled to the DC-DC converter; and
a control circuit coupled to the charge pump and the switching network, the control circuit configured to route power from the charge pump to a switch within the switching network.

2. The power management system of claim 1, wherein the switching network comprises an N-type field effect transistor (NFET).

3. The power management system of claim 2, wherein the control circuit is configured to route power to a gate of the NFET.

4. The power management system of claim 1, further comprising a second charge pump coupled to the DC-DC converter and the control circuit.

5. The power management system of claim 4, wherein the charge pump is configured to provide a first voltage that is an integer multiple of a battery voltage and the second charge pump is configured to provide a second voltage that is a different integer multiple of the battery voltage.

6. The power management system of claim 1, wherein the switching network is configured to be coupled to a front-end module (FEM).

7. The power management system of claim 1, further comprising a second DC-DC converter coupled to the switching network.

8. The power management system of claim 1, wherein the DC-DC converter comprises a buck-boost DC-DC converter.

9. The power management system of claim 1, wherein the switching network comprises a battery bypass switch.

10. A mobile terminal comprising a power management system comprising:
a power management chip comprising:
a first charge pump;
a first direct current-to-direct current (DC-DC) converter coupled to the first charge pump;
a switching network coupled to the first DC-DC converter; and
a control circuit coupled to the first charge pump and the switching network, the control circuit configured to route power from the first charge pump to a switch within the switching network; and
a first front-end module coupled to the switching network.

11. The mobile terminal of claim 10, wherein the switching network comprises a plurality of N-type field effect transistors (NFETs), including at least one bypass switch.

12. The mobile terminal of claim 11, wherein the control circuit is configured to route power from the first charge pump to a gate of at least one of the plurality of NFETs.

13. The mobile terminal of claim 10, wherein the power management chip comprises a second charge pump and a second DC-DC converter, wherein the control circuit is coupled to the second charge pump, and wherein the second DC-DC converter is coupled to the switching network.

14. The mobile terminal of claim 10, wherein the switching network comprises a current limiting circuit coupled to at least one switch.

15. The mobile terminal of claim 10, further comprising a plurality of FEMs coupled to the switching network.

16. A method for controlling a switching circuit, comprising:
responsive to receiving information from an external source, activating one or more charge pumps; and
turning on one or more n-type field effect transistor (NFET) switches to couple at least one of the one or more charge pumps to a front-end module FEM).

17. The method of claim 16, further comprising using a battery bypass switch to couple a battery voltage source to the FEM.

18. The method of claim 16, further comprising receiving the information from the external source.

19. The method of claim 16, further comprising providing power from the at least one of the one or more charge pumps to a control circuit.

20. The method of claim 19, further comprising biasing gates of the one or more NFET switches using the control circuit.
